(19) United States
(12) Patent Application Publication
(10) Pub. No.: US 2010/0060143 A1
(43) Pub. Date: Mar. 11, 2010

(54) Color stabilized light source having a thermally conductive luminescent element and a light emitting diode

(76) Inventors: Scott M. Zimmerman, Basking Ridge, NJ (US); Karl W. Beeson, Princeton, NJ (US); William R. Livesay, San Diego, CA (US)

Correspondence Address: Goldeneye, Inc., Suite 233, 9747 Businesspark Avenue, San Diego, CA, 92131, US

(21) Appl. No.: 12/583,499

(22) Filed: Aug. 20, 2009

Related U.S. Application Data
(60) Provisional application No. 61/189,652, filed on Aug. 21, 2008.

(51) Int. Cl. H01L 33/44

(52) U.S. Cl. 313/501

(57) ABSTRACT

A color stabilized light source has a thermally conductive luminescent element in conjunction with a light emitting diode. A thermal pathway through the LED allows the thermally conductive luminescent element to maintain its output level even at high flux levels.

### REFERENCE TO PRIOR APPLICATION

This application claims the benefit of U.S. Provisional Patent Application Ser. No. 61/189,652, which was filed on Aug. 21, 2008, which is herein incorporated by reference.

### BACKGROUND OF THE INVENTION

Wavelength conversion materials are extensively used in the solid state lighting applications. Wavelength conversion materials or luminescent elements will convert light of a first color or wavelength into light of a second color or wavelength.

Typically powder phosphors are mixed with an organic binder system to form a luminescent element and deposited on the LED directly or at a distance as discussed by various authors as “phosphor at a distance”. While this approach is sufficient for low level light outputs, the luminescent element has significant shortcomings at high flux levels. The binder degrades due to photochemical effects especially in the presence of moisture. Thermal quenching effects on the converted light becomes important as the flux levels increase.

U.S. Pending patent application Ser. No. 12/380,439 for “Fixtures for Large Area Directional and Isotropic Solid State Lighting Panels” and U.S. Pending patent application Ser. No. 12/383,567 for “High Quality Luminescent Materials for Solid State Lighting Applications”, commonly assigned as the present application and herein incorporated by reference, have demonstrated that the formation of thermally conductive luminescent elements can be used to increase the useful range of the phosphors by providing a thermal conduction pathway for maintaining the wavelength conversion material at a lower temperature. It is desirable that the wavelength spectrum of these solid state lighting sources be controllable. At high current levels, the LEDs themselves shift their spectrum of the light they emit.

Wavelength conversion materials change their efficiency as a function of temperature. These effects are typically not seen in low level flux applications. However at high flux levels, especially for powders with little thermal conductivity or means of cooling, these effects can be as significant as the efficiency and color shifts associated with the LED itself. The present invention discloses methods and light sources whereby these color shifts caused by temperature changes to the wavelength conversion materials in the luminescent elements can be controlled or eliminated and stabilize the color of light emitted by the light source.

As an example, a blue LED with a yellow Ce:Yag powder phosphor contained within an organic binder typically has an increasing color temperature with increasing current level to the LED. This color shift is a function of the Ce:Yag experiencing a reduction in lumen output due to thermal quenching effects. Most luminescent materials, including quantum dots, isolated ions, organic and inorganic phosphors, exhibit thermal spectrum and output level changes versus temperature. The LED in this example is a GaN based LED which exhibits a blue shift with increasing current level. As such, the blue lumens are decreasing as the current increases. If the phosphor output level were stable, one would expect a decreasing color temperature. This decreasing color temperature typically is not the case because the rate at which the phosphor lumen output is decreasing is much higher than the rate at which the blue LED lumen output is decreasing, which leads to an overall increase in color temperature.

FIG. 1 depicts the spectrum of both a blue LED 5 and a yellow Ce:Yag phosphor 6. The Ce:Yag phosphor emits yellow light when subjected to blue or ultraviolet light. It is used with a blue LED in white light-emitting diodes, converting part of the blue light into yellow, which then appears as white.

FIG. 1 also shows the change of spectrum/intensity for the blue LED 8 and yellow phosphor 7. In the case of the blue LED, the emitted light spectrum 5 typically shifts towards the shorter wavelengths, as depicted in wavelength shift 9. Conversely the phosphor spectrum 6 tends to maintain its spectral shape but loses intensity due to thermal quenching effects. This is depicted in intensity drop 10. Combinations of these spectral shifts 9 and intensity changes 10 can occur in both LEDs and luminescent materials. It is also desirable that the maximum efficiency for a light source be obtained to reduce the power required to generate light. The optimum dopant concentration in powder based systems is determined based on the overall optical efficiency. This is a complicated optical problem, which is related to the backscatter and absorption characteristics of both the phosphor system of the luminescent element and the LED itself.

The present invention teaches methods and light sources which increase efficiency of the overall light source by controlling backscatter within the solid luminescent element such that a more optimum dopant concentration can be used with less concentration quenching.

### SUMMARY OF THE INVENTION

The present invention discloses a color stabilized light source, which has a thermally conductive luminescent element in conjunction with a light emitting diode. This color stabilized light source does not color shift in the same manner as powder based wavelength conversion material at high flux levels.

The present invention teaches that the output level of the thermally conductive luminescent element can be maintained even at high flux levels if a thermal conduction path, either through the LED or through some other thermal pathway, is provided.

The thermal conduction path enhances the efficiency of the light source and also affects the color temperature shift that occurs within the light source. Thermally conductive luminescent elements can enhance efficiency and/or color temperature control at high flux levels. Even more preferably the combination of LED color shift and phosphor intensity changes leads to inherently stable color temperature sources over an extended current drive level.

Alternately, the combination of LED color shift and phosphor intensity changes to create a particular color temperature change versus drive level. These color stabilized light sources can be used in general illumination, display cases, food displays, museums and other color critical illumination applications. The dynamic control of the color temperature is based on using at least one stabilized color source and at least one other color source. More preferably, dynamically controlled color sources in projection application can reduce the binning requirements for LEDs. Even more preferably, passively or dynamically controlled color sources can create green/yellow, orange/red, and/or cyan/blue sources to extend or provide adjustable color gamut for displays including but not limited to projection, LCD backlights, LED displays, and fixed format.

### BRIEF DESCRIPTION OF THE DRAWINGS

FIG. 1 depicts a graph showing typical spectral/intensity shifts of the LED and phosphor powders.

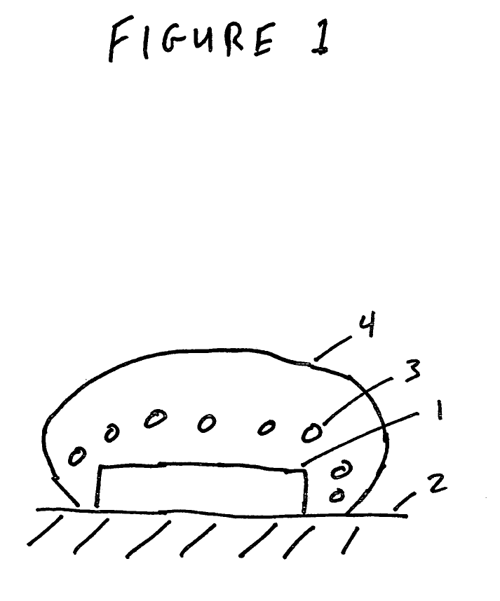

FIG. 2 depicts a first embodiment of a color stabilized light source with a thermally conductive luminescent element and a LED of the present invention

FIG. 3 depicts a solid luminescent element plus LED color temperature shift and a powder phosphor plus LED color temperature shift versus current.

FIG. 4 depicts a second embodiment of a solid luminescent element plus LED with a stabilized color temperature versus current of the present invention.

FIGS. 5A to 5D depict different schematics of the thermal impedance paths for stabilizing the color temperature versus current of the light source of the present invention.

FIG. 6 depicts the spectrum of a typical green LED plus a Ce:Yag/Blue LED with a dominant wavelength of 545 nm of the present invention.

FIG. 7 depicts a control circuit for shifting the relative ratio of the LED and the stabilized color temperature light source of the present invention.

FIG. 8 depicts a light bulb with a stabilized color temperature light source of the present invention.

FIG. 9 depicts a projector with color temperature tunable light sources of the present invention.

FIG. 10 depicts a LCD backlight with color temperature tunable light sources of the present invention.

FIG. 11 depicts a light source with a negative sloped color temperature of the present invention.

### DETAILED DESCRIPTION OF THE INVENTION

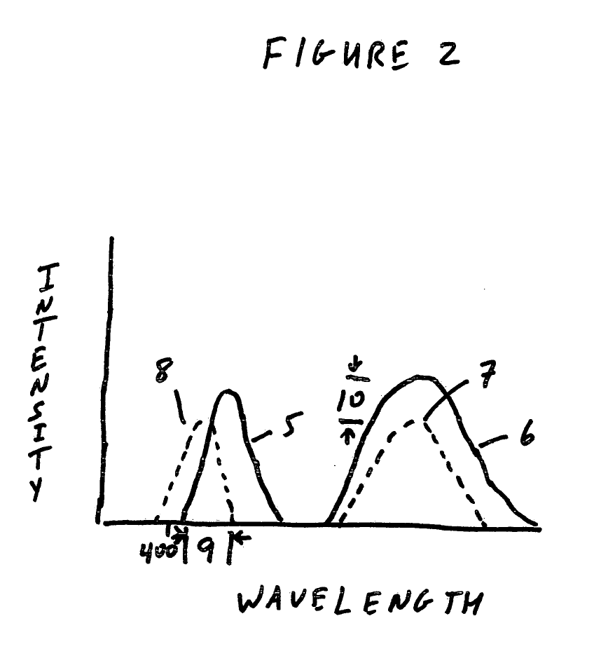

FIG. 2 depicts a first embodiment of a color stabilized light source 20 with a thermally conductive luminescent element 22 and a LED 24 of the present invention. The first or lower surface 26 of the LED is on a mounting surface 28. The thermally conductive luminescent element 22 is deposited or grown on the second or upper surface 30 of the LED.

The thermally conductive luminescent element 22 is formed from wavelength conversion materials. The wavelength conversion materials absorb light in a first wavelength range and emit light in a second wavelength range, where the light of a second wavelength range has longer wavelengths than the light of a first wavelength range. The wavelength conversion materials may be, for example, phosphor materials or quantum dot materials. The thermally conductive luminescent element may be formed from two or more different wavelength conversion materials. The thermally conductive luminescent element may also include optically inert host materials for the wavelength conversion materials of phosphors or quantum dots. Any optically inert host material must be transparent to ultraviolet and visible light.

Phosphor materials are typically optical inorganic materials doped with ions of lanthanide (rare earth) elements or, alternatively, ions such as chromium, titanium, vanadium, cobalt or neodymium. The lanthanide elements are lanthanum, cerium, praseodymium, neodymium, promethium, samarium, europium, gadolinium, terbium, dysprosium, holmium, erbium, thulium, ytterbium and lutetium. Optical inorganic materials include, but are not limited to, sapphire (Al.sub.2O.sub.3), gallium arsenide (GaAs), beryllium aluminum oxide (BeAl.sub.2O.sub.4), magnesium fluoride (MgF.sub.2), indium phosphide (InP), gallium phosphide (GaP), yttrium aluminum garnet (YAG or Y.sub.3Al.sub.5O.sub.12), terbium-containing garnet, yttrium-aluminum-lanthanide oxide compounds, yttrium-aluminum-lanthanide-gallium oxide compounds, yttrium oxide (Y.sub.2O.sub.3), calcium or strontium or barium halophosphates (Ca,Sr,Ba).sub.5(PO.sub.4).sub.3(Cl,F), the compound CeMgAl.sub.11O.sub.19, lanthanum phosphate (LaPO.sub.4), lanthanide pentaborate materials ((lanthanide)(Mg,Zn)B.sub.5O.sub.10), the compound BaMgAl.sub.10O.sub.17, the compound SrGa.sub.2S.sub.4, the compounds (Sr,Mg,Ca,Ba)(Ga,Al,In).sub.2S.sub.4, the compound SrS, the compound ZnS and nitridosilicate. There are several exemplary phosphors that can be excited at 250 nm or thereabouts. An exemplary red emitting phosphor is Y.sub.2O.sub.3:Eu.sup.3+. An exemplary yellow emitting phosphor is YAG:Ce.sup.3+. Exemplary green emitting phosphors include CeMgAl.sub.11O.sub.19:Tb.sup.3+, ((lanthanide)PO.sub.4:Ce.sup.3+,Tb.sup.3+) and GdMgB.sub.5O.sub.10:Ce.sup.3+,Tb.sup.3+. Exemplary blue emitting phosphors are BaMgAl.sub.10O.sub.17:Eu.sup.2+ and (Sr,Ba,Ca).sub.5(PO.sub.4).sub.3Cl:Eu.sup.2+. For longer wavelength LED excitation in the 400-450 nm wavelength region or thereabouts, exemplary optical inorganic materials include yttrium aluminum garnet (YAG or Y.sub.3Al.sub.5O.sub.12), terbium-containing garnet, yttrium oxide (Y.sub.2O.sub.3), YVO.sub.4, SrGa.sub.2S.sub.4, (Sr,Mg,Ca,Ba)(Ga,Al,In).sub.2S.sub.4, SrS, and nitridosilicate. Exemplary phosphors for LED excitation in the 400-450 nm wavelength region include YAG:Ce.sup.3+, YAG:Ho.sup.3+, YAG:Pr.sup.3+, YAG:Tb.sup.3+, YAG:Cr.sup.3+, YAG:Cr.sup.4+, SrGa.sub.2S.sub.4:Eu.sup.2+, SrGa.sub.2S.sub.4:Ce.sup.3+, SrS:Eu.sup.2+ and nitridosilicates doped with Eu.sup.2+.

Luminescent materials based on ZnO and its alloys with Mg, Cd, Al are preferred. More preferred are doped luminescent materials of ZnO and its alloys with Mg, Cd, Al which contain rare earths, Bi, Li, Zn, as well as other luminescent dopants. Even more preferred is the use of luminescent elements which are also electrically conductive, such a rare earth doped AlZnO, InZnO, GaZnO, InGaZnO, and other transparent conductive oxides of indium, tin, zinc, cadmium, aluminum, and gallium. The use of these transparent conductive oxides, oxynitrides and nitrides which are also luminescent as both interconnect means and/or wavelength conversion means is also an embodiment of this invention. Other phosphor materials not listed here are also within the scope of this invention.

Quantum dot materials are small particles of inorganic semiconductors having particle sizes less than about 30 nanometers. Exemplary quantum dot materials include, but are not limited to, small particles of CdS, CdSe, ZnSe, InAs, GaAs and GaN. Quantum dot materials can absorb light at first wavelength and then emit light at a second wavelength, where the second wavelength is longer than the first wavelength. The wavelength of the emitted light depends on the particle size, the particle surface properties, and the inorganic semiconductor material.

The transparent and optically inert host materials are especially useful to spatially separate quantum dots. Host materials include polymer materials and inorganic materials. The polymer materials include, but are not limited to, acrylates, polystyrene, polycarbonate, fluoroacrylates, chlorofluoroacrylates, perfluoroacrylates, fluorophosphinate polymers, fluorinated polyimides, polytetrafluoroethylene, fluorosilicones, sol-gels, epoxies, thermoplastics, thermosetting plastics and silicones. Fluorinated polymers are especially useful at ultraviolet wavelengths less than 400 nanometers and infrared wavelengths greater than 700 nanometers owing to their low light absorption in those wavelength ranges. Exemplary inorganic materials include, but are not limited to, silicon dioxide, optical glasses and chalcogenide glasses.

The light emitting diode 24 can be fabricated by epitaxially growing multiple layers of semiconductors on a growth substrate. Inorganic light-emitting diodes can be fabricated from GaN-based semiconductor materials containing gallium nitride (GaN), aluminum nitride (AIN), aluminum gallium nitride (AlGaN), indium nitride (InN), indium gallium nitride (InGaN) and aluminum indium gallium nitride (AlInGaN). Other appropriate materials for LEDs include, for example, aluminum gallium indium phosphide (AlGaInP), gallium arsenide (GaAs), indium gallium arsenide (InGaAs), indium gallium arsenide phosphide (InGaAsP), diamond or zinc oxide (ZnO).

Especially important LEDs for this invention are GaN-based LEDs that emit light in the ultraviolet, blue, cyan and green regions of the optical spectrum. The growth substrate for GaN-based LEDs is typically sapphire (Al.sub.2O.sub.3), silicon carbide (SiC), bulk gallium nitride or bulk aluminum nitride.

The color stabilized light source 20 can be a blue or ultraviolet emitting LED used in conjunction with a thermally conductive luminescent element one or more wavelength conversion materials such as phosphors or quantum dots that convert at least some of the blue or ultraviolet light to other wavelengths. For example, combining a yellow phosphor with a blue emitting LED can result in a white light source. The yellow phosphor converts a portion of the blue light into yellow light. Another portion of the blue light bypasses the yellow phosphor. The combination of blue and yellow light appears white to the human eye. Alternatively, combining a green phosphor and a red phosphor with a blue LED can also form a white light source. The green phosphor converts a first portion of the blue light into green light. The red phosphor converts a second portion of the blue light into green light. A third portion of the blue light bypasses the green and red phosphors. The combination of blue, green and red light appears white to the human eye. A third way to produce a white light source is to combine blue, green and red phosphors with an ultraviolet LED. The blue, green and red phosphors convert portions of the ultraviolet light into, respectively, blue, green and red light. The combination of the blue, green and red light appears white to the human eye.

The color stabilized white light source 20 of FIG. 2 has a blue gallium nitride LED 24 and a thermally conductive luminescent element 22 having a yellow YAG:Ce.sup.3+ phosphor 32 in an inorganic binder 34. The mounting surface 28 of the LED can be a heat sink 36 to further flow heat away from the thermally conductive luminescent element and the LED.

Heat will flow from the thermally conductive luminescent element 22 through the adjacent LED. The combination of the light shift of the LED and the maintenance of the intensity of the thermally conductive luminescent element can be used to control color temperature and efficiency of a blue LED with a yellow phosphor. In this particular example, the color temperature of the combined blue and yellow spectrum versus current is determined by the rate of change in the blue spectrum and yellow spectrum. The thermal, electrical, and combinations of sources can stabilize the color temperature over a range of currents. The articles that perform those functions are embodiments of this invention.

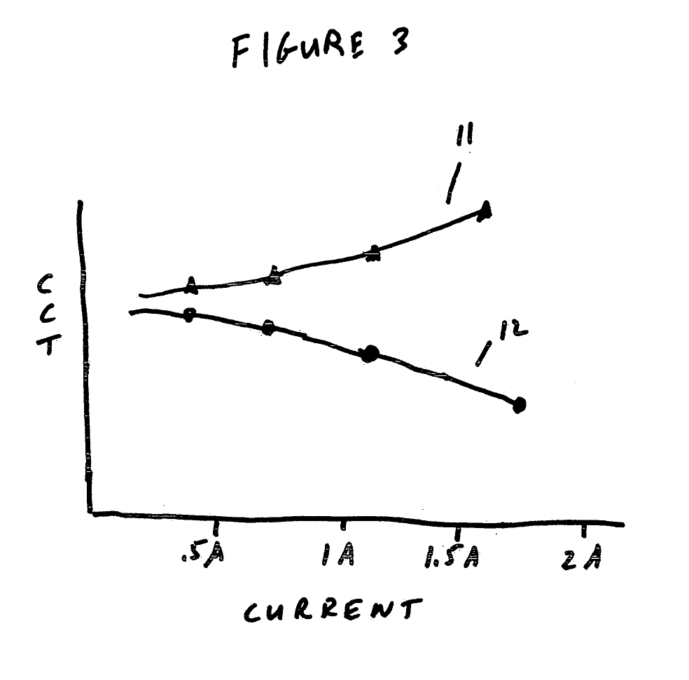

FIG. 3 depicts the color temperature change or correlated color temperature (CCT) versus drive current for a powder phosphor white light source 41 and a thermally conductive luminescent element white light source 42. In this case, because the temperature of the thermally conductive luminescent element white light source 42 can be controlled at a much lower temperature, its rate of change in output is less than the rate of change in the output of the blue LED being used to excite the yellow thermally conductive luminescent element. The color temperature is reduced versus current. A solid luminescent element creates this effect. The combination of the powder and thermally conductive luminescent elements creates a light source with substantially lower change in color temperature versus current.

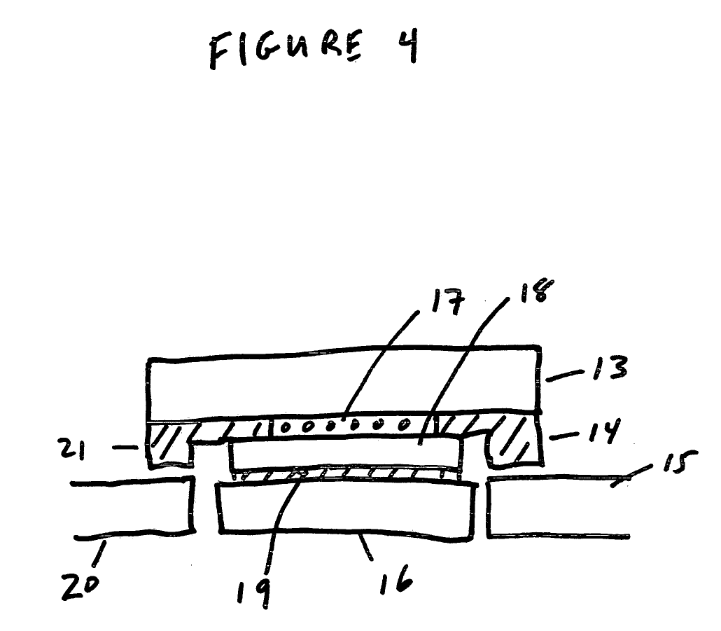

FIG. 4 depicts a second embodiment of a color stabilized light source 50. LED 52 is attached to heatsink 54, via attachment means 56. The thermally conductive luminescent element 58 is attached to LED 52 via encapsulant 60 and interconnects 62 and 64, which may include but not limited to metals, transparent conductive oxides or conductive inks and pastes. Alternately, a vertical structure may be used whereby interconnect is via attachment means 56 and at least one of interconnects 62 and 64. Encapsulant 60 may include organic and inorganic materials with thermal conductivities ranging from 0.01 W/m/K to 3000 W/m/K. The encapsulant 60 can be excluded to form an air gap to thermally isolate thermally conductive luminescent element 58 from LED 52. Thermally conductive luminescent element 58 may also be thermally cooled via heatsinks 66 and 68 using interconnects 62 and 64 respectively or other thermally conductive attachment means including conductive inks, pastes, mechanical attachment and physical contact. Heatsinks 54, 66 and 68 may be isolated and/or attached to each other thermally and/or electrically. Heating means (not shown) can shift the spectrum of either or both the LED 52 or thermally conductive luminescent element directly or via heatsinks 54, 66 and/or 68.

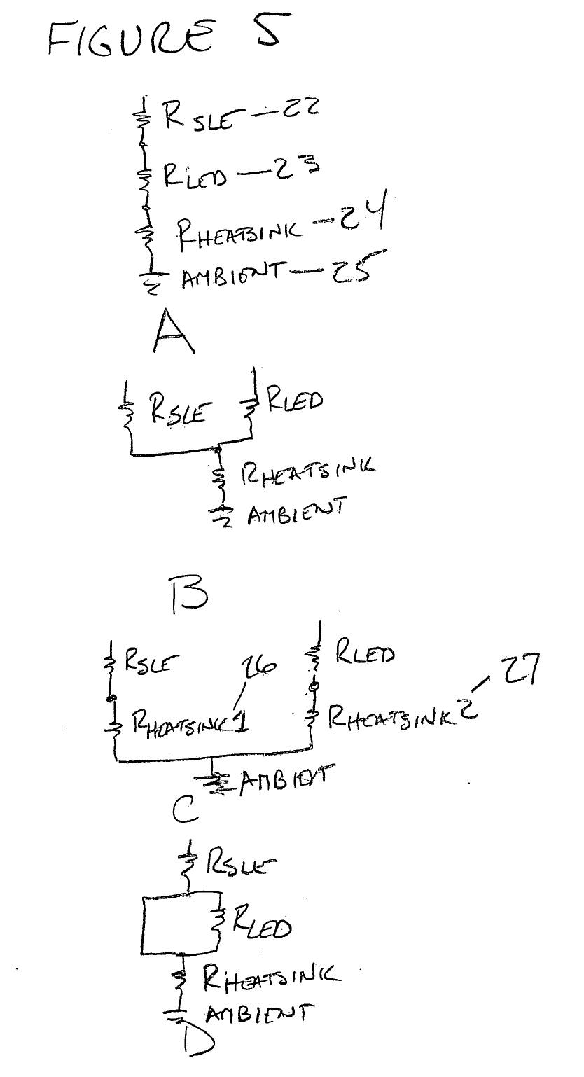

FIGS. 5A, 5B; 5C and 5D depict schematically various thermal impedance paths that can be created to control the color temperature of the light source. Thermal impedance for the thermally conductive luminescent element and the thermal impedance for the LED are depicted in series in FIG. 5A, parallel in FIG. 5B, series/parallel in FIG. 5C, and separate modes in FIG. 5D.

The thermal impedance of the heatsink to ambient is also depicted. Combinations or arrays of elements such as two heatsink can be used. Both steady state and transient thermal responses are embodiments of this invention. More preferably the thermal impedance of sources in high current pulsed mode are also embodiments of this invention.

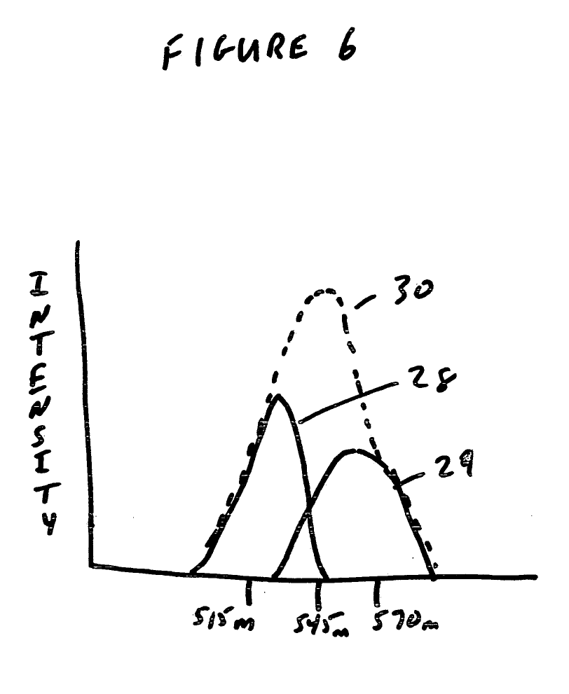

FIG. 6 depicts the spectrum of a combined green light source 100 of a blue LED and a yellow thermally conductive luminescent element at approximately 545 nm containing at least one LED spectrum 102 at approximately 515 nm and thermally conductive luminescent source spectrum 104 at approximately 570 nm. The variability of the LED spectrum 102 from the standpoint of binning variation, thermal variation and current drive level variation is compensated for by the thermally conductive luminescent source spectrum 104. Additionally, a more useful green light with a dominant wavelength between the two dominant wavelengths of the individual light sources is created. In this manner, high efficiency yellow green sources with dominate wavelengths greater than 520 nm can be created. These combined sources are an embodiment of this invention. These sources can be used in lighting, displays, and other color sensitive applications. The wavelength combining means will maintain small etendue sources such as, but not limited to, dichroics and other wavelength dependent elements. The sequencing and combinations of sequencing and CW can control the spectrum.

Unlike powder phosphor approaches, the thermally conductive luminescent element source can maintain high output levels at high excitation levels. This enables the formation of very high brightness sources with combined lumens/mm2 at 1 A exceeding 200 lumens/mm2 with dominate wavelengths well into the classic “green gap” which is known in the art. This technique to creates sources with high output both in the visible, UV and infrared. In the case of red sources, AlinGaP as well as other red LED sources tend to exhibit a shift towards longer wavelength.

Conversely, the radiance efficiency of AlinGap LED in particular increases at longer wavelengths but the luminous efficiency decreases due to the eye response dropping off at longer wavelengths. In this case, a more efficient source can be created by combining an efficient long wavelength AlinGap source with a thermally conductive luminescent element source at shorter wavelength where the combination creates a dominate wavelength at a longer wavelength than typically possible with the thermally conductive luminescent element source. The longer the wavelength of the thermally conductive luminescent element source the larger the stokes shift losses. In addition, a very limited set of efficient red phosphors presently exists in solid state lighting. This technique overcomes the red deficiency in solid state lighting. More preferably, orange/red thermally conductive luminescent elements will form combined sources in the spectrum range. The orange/red thermally conductive luminescent element can be used to correct for the shift to longer wavelength. Similar techniques can be used in all ranges of the visible, UV and infrared spectrum. The use of these techniques both dynamically or statically are embodiments of this invention.

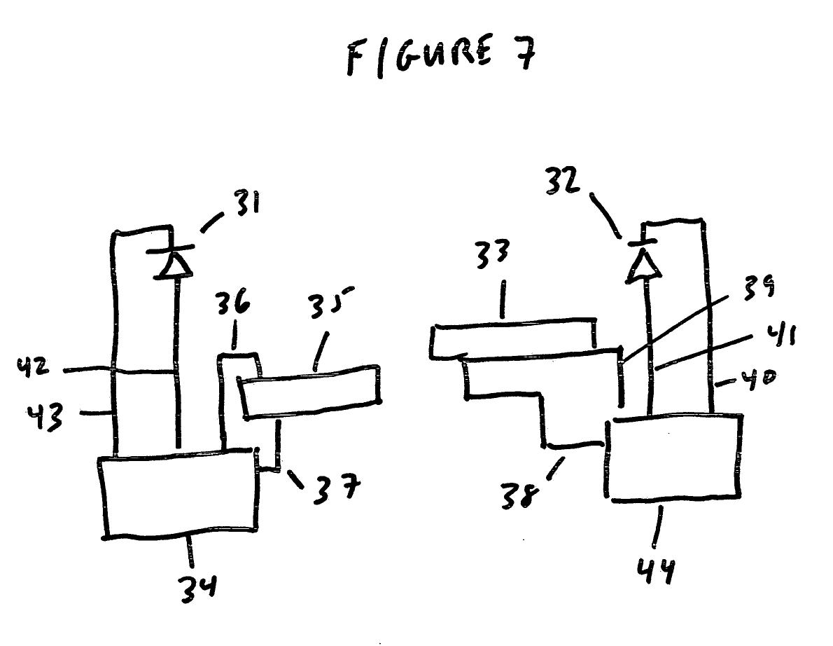

FIG. 7 depicts schematically the active control of at least one LED 200 and one thermally conductive luminescent element source 202 using at least one photoresponsive device 204 to the thermally conductive luminescent element source 202 and/or at least one photoresponsive device 206 to the LED 200. Source interconnects 208 and 210 connect the source to control module 212 for the one photoresponsive device 204 to the thermally conductive luminescent element source 202. Source interconnects 214 and 216 connect the source to control module 218 for the one photoresponsive device 206 to the LED 200.

Photoresponsive device 204, which may consist of but not limited to photodiodes, phototransistors, and other devices which change electrical parameters upon exposure to light, are also connected to control module 212 via control interconnect 220 and 222.

Photoresponsive devices 206, which may consist of but not limited to photodiodes, phototransistors, and other devices which change electrical parameters upon exposure to light, are also connected to control module 218 via control interconnect 224 and 226.

The output of at least one photoresponsive device 204 and/or 206 are used to control the drive levels of one and/or both sources 202 and 200. The use of pulse width modulation, amplitude modulation, and/or a combination of both to increase or decrease the intensity of sources 33 and/or 35 is an embodiment of this invention.

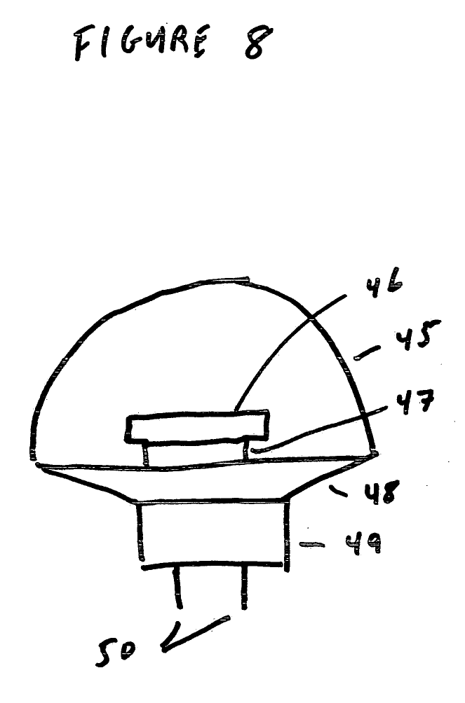

FIG. 8 depicts a color stabilized light bulb 300. The light bulb consists at least one LED 302 exciting at least one thermally conductive luminescent element 304. As depicted schematically in FIG. 5, various thermal impedance paths may be used to determine the operational temperature of both thermally conductive luminescent element 304 and at least one LED 302. The rate of change in output of the thermally conductive luminescent element 304 and at least one LED 302 cancel each other out over the majority of the drive conditions for the light source leading to a stable color temperature over the range of drive levels and temperatures. An external optical element can create various optical output distributions ranging from directional to diffuse. Power conditioning means 306 and contact means 308 can interface color stabilized light bulbs 300 to existing power and fixture requirements as known in the art.

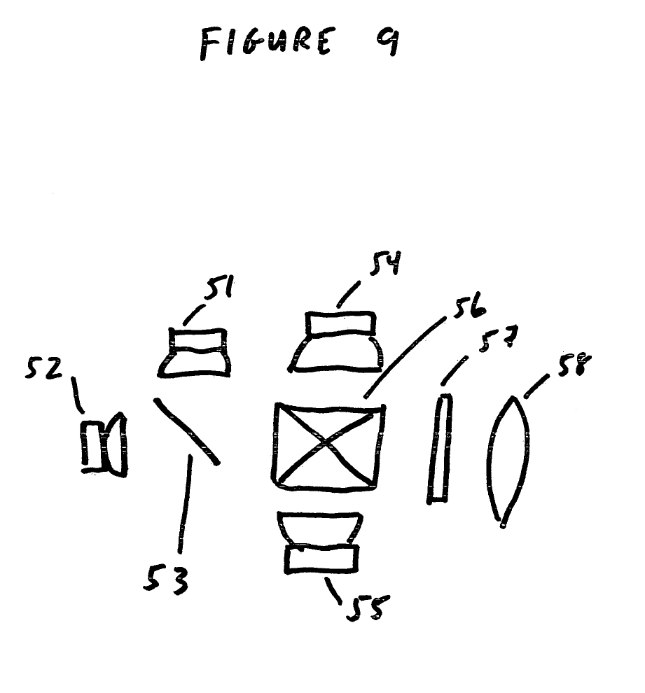

FIG. 9 depicts a projection system 400 utilizing at least one color stabilized light source 402. A dichroic combiner 404 and different wavelength LED source 406 create at least one enhanced spectrum input for the projector. Further color combining means 408 including, but not limited to, X cubes, dichroics, polarization combining elements and optical elements, can add in additional wavelength sources 410 and 412. These combined sources can use a spatial light modulator 414 including, but not limited to, DLP, LCOs, LCD, dynamic gratings, Liquid crystal tunable gratings and other modulators. The use of recycling techniques, both as they relate to wavelength and polarization, are also embodiments. An image can be formed from the output of the spatial light modulator 416 via an optic 418, both refractive and/or reflective, or a combination of both at a distance n.

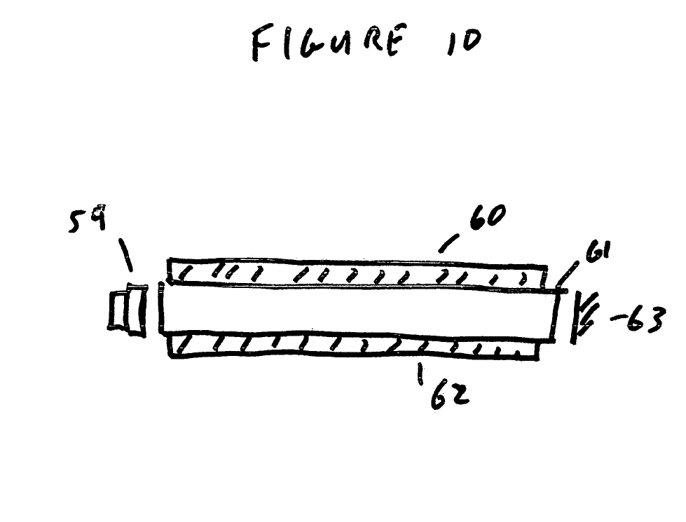

FIG. 10 depicts a backlight 500 containing at least one color controllable source 502. The use of spreading means 504, which may consist of but not limited to spectral, polarization, and intensity spreading, to distribute the output from color controllable source 502 is an embodiment of this invention. More preferably at least one color controllable source 502 can enhance color rendering in a dynamically dimmed backlight. The recycling means 506 can recycling light back to the light source 502 to enhance uniformity of wavelength, polarization, and/or intensity. The extraction and reflection means 508 and 510 can redirect the light in a particular direction with a desired polarization and/or distribution.

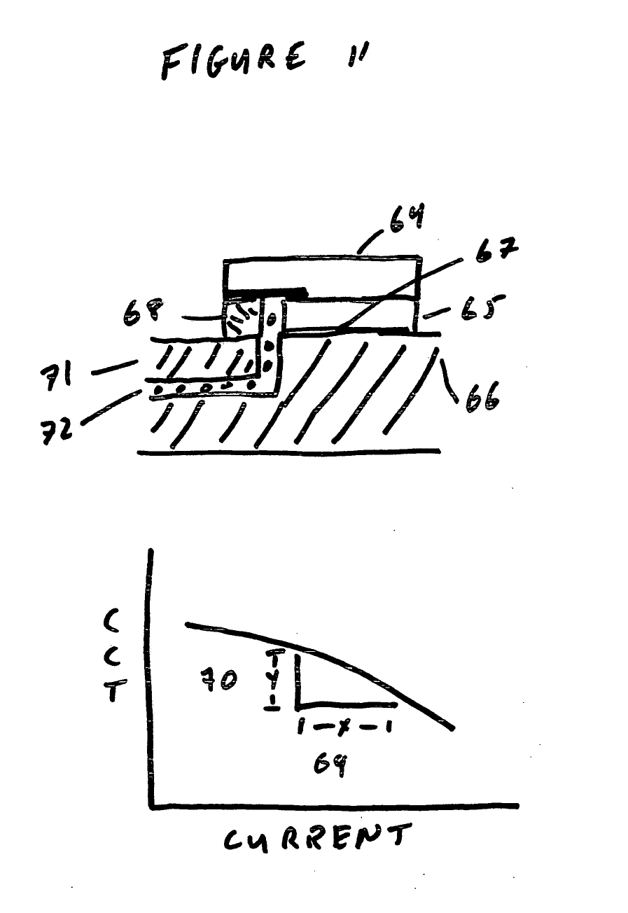

FIG. 11 depicts a solid state light source 600 exhibiting a controllable slope for color temperature versus current. In this example, a vertical LED 602 is attached electrically and thermally to a first heatsink 604 via a reflective contact 606. Vertical LED 602 has a top contact (not shown in the Figure) made via interconnect 608, which may consist of but not limited to metals, transparent oxides, and/or conductive inks and pastes which is electrically and thermally connected to a second heatsink 610. A dielectric layer 612 electrically isolates but thermally connects first heatsink 604 to second heatsink 610. The interconnect 608 is formed into a solid luminescent element 614. By controlling the thermal impedance of heatsinks 604 and 610, it is possible to modify the slope of color temperature versus current as described by delta y 616 and delta x 618. The ratio of these two values defines the slope of the color temperature versus current. The use of this technique and the articles, which use this technique, are embodiments of this invention. More preferably the y/x ratios of the slope of color temperature versus current should be less than or equal to zero for the present invention.

While the invention has been described with the inclusion of specific embodiments and examples, it is evident to those skilled in the art that many alternatives, modifications and variations will be evident in light of the foregoing descriptions. Accordingly, the invention is intended to embrace all such alternatives, modifications and variations that fall within the spirit and scope of the appended claims.

1. A color stabilized light source comprising
a light emitting diode emitting light of a first color; and
a thermally conductive luminescent material on said light emitting diode, said thermally conductive luminescent material for converting light of a first color from said light emitting diode into light of a second color.

2. The color stabilized light source of claim 1 wherein heat generated from said thermally conductive luminescent material flows through said light emitting diode.

3. The color stabilized light source of claim 1 further comprising
a heatsink, said light emitting diode on said heatsink, wherein heat flows from said light emitting diode through said heatsink.

4. The color stabilized light source of claim 1 wherein said light emitting diode emits light of blue color and said thermally conductive luminescent material converts said light of blue color from said light emitting diode into light of yellow color to form a color stabilized white light source.

5. The color stabilized light source of claim 1 wherein said light emitting diode emits light of blue color and said thermally conductive luminescent material converts said light of blue color from said light emitting diode into light of yellow color to form a color stabilized green light source.

6. The color stabilized light source of claim 1 wherein said color stabilized light source forms a color stabilized light bulb.

7. The color stabilized light source of claim 1 wherein said color stabilized light source forms a projection system.

8. The color stabilized light source of claim 1 wherein said color stabilized light source forms a backlight.
